(19) United States
(12) Patent Application Publication
(10) Pub. No.: US 2009/0268421 A1
(43) Pub. Date: Oct. 29, 2009

(54) SHIELDING ASSEMBLY

(75) Inventor: HUNG-CHEN WU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/327,440

(22) Filed: Dec. 3, 2008

(30) Foreign Application Priority Data
Apr. 25, 2008 (TW) 97115442

(51) Int. Cl. H05K 7/00

(52) U.S. Cl. 361/800

(57) ABSTRACT

A shielding assembly (10) for electronic device is provided. The shielding assembly (10) includes a base frame (14) and a cover (16). The base frame (14) includes a peripheral wall (142). The peripheral wall (142) encloses a receiving space (144). The peripheral wall (142) is defined a groove (149) surrounding the receiving space (144). The cover (16) cover the receiving space (144), the cover (16) has a side wall corresponding to and being engaged with the groove (149) of the base frame (14).

### BACKGROUND

1. Field of the Invention

The exemplary invention relates to shielding assemblies and, particularly to shielding assemblies used in portable electronic devices.

2. Description of Related Art

A typical shielding assembly may usually comprise a cover and a base frame mounted on a printed circuit board (PCB). Flanges are bent from outer edges of the cover and define multiple apertures therethrough. The base frame comprises side walls with a plurality of dome-shaped projections for engaging the apertures when the shielding assembly is in a closed position. However, the cover may firmly engage the base frame only when the dome-shaped projections are precisely aligned with the apertures. Thus, it can be hard to assemble the shielding assembly.

Therefore, there is a room for improvement within the art.

### BRIEF DESCRIPTION OF THE DRAWINGS

Many aspects of the exemplary shielding assembly can be better understood with reference to the following drawings. These drawings are not necessarily drawn to scale, the emphasis instead being placed upon clearly illustrating the principles of the exemplary shielding assembly. Moreover, in the drawings like reference numerals designate corresponding parts throughout the several views. Wherever possible, the same reference numbers are used throughout the drawings to refer to the same or like elements of an embodiment.

FIG. 1 is an exploded view of a portion of a portable electronic device with a shielding assembly according to an exemplary embodiment.

FIG. 2 is an exploded view of the portable electronic device in FIG. 1 from an another view thereof.

FIG. 3 is an enlarged view of a base frame of the shielding assembly in FIG. 1.

FIG. 4 is an assembled view of the portion of the portable electronic device in FIG. 1.

FIG. 5 is a cross-sectional view of the portion of the portable electronic device in FIG. 4.

FIG. 6 is partially enlarged view of the portion of the portable electronic device in FIG. 5.

### DETAILED DESCRIPTION OF THE EMBODIMENTS

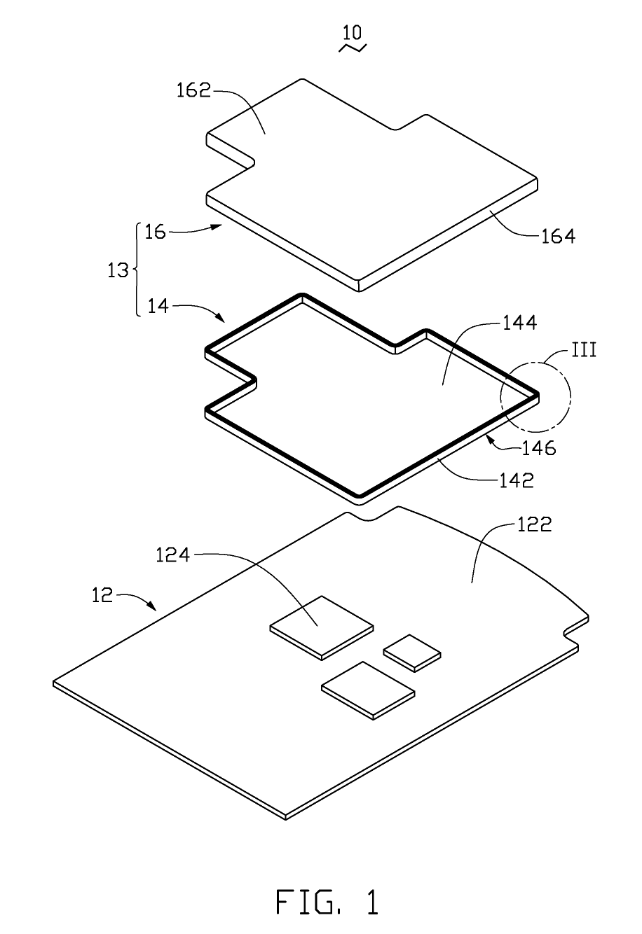

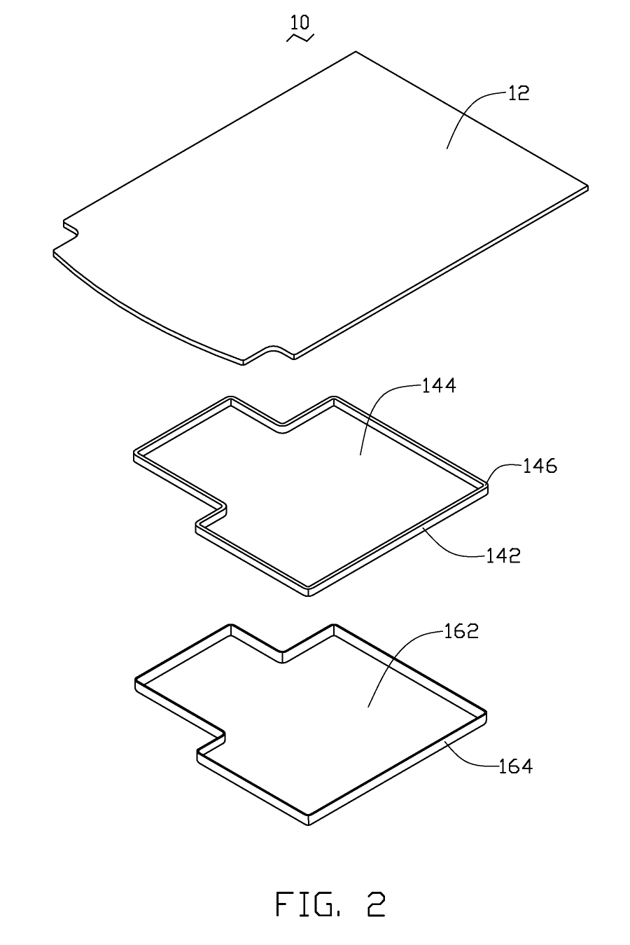

Referring to FIGS. 1 and 2, a portion of an exemplary portable electronic device in the form of a mobile phone 10 may include a circuit board 12 and a shielding assembly 13 attached to the circuit board 12. The shielding assembly 13 includes a base frame 14 mounted to the circuit board 12 and a cover 16 for engaging the base frame 14.

The circuit board 12 is generally rectangular and includes a surface 122 facing the base frame 14. The surface 122 typically has a number of electronic components 124, such as, capacitors and resistors, mounted thereon,.

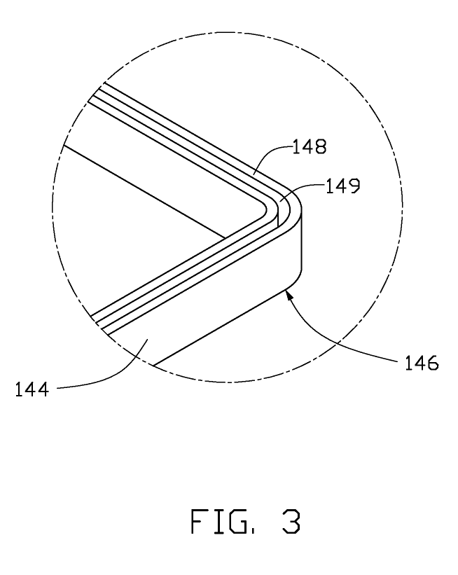

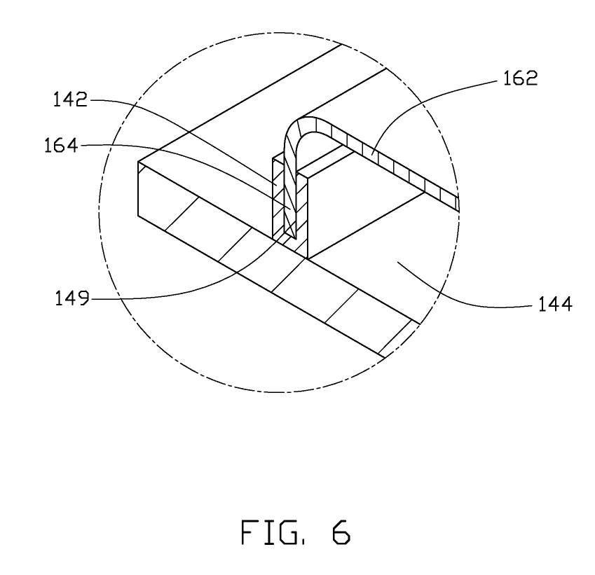

The base frame 14 has a peripheral wall 142 enclosing a receiving space 144 for accommodating the electronic components 124. The peripheral wall 142 includes a first surface 146 and a second surface 148 (shown in FIG. 3). The first surface 146 is configured for attaching the base frame 14 to the circuit board 12 (FIG. 6). The second surface 148 faces the cover 16 and defines a groove 149 (shown in FIG. 3) surrounding the receiving space 144. The groove 149 is for engaging with the cover 16.

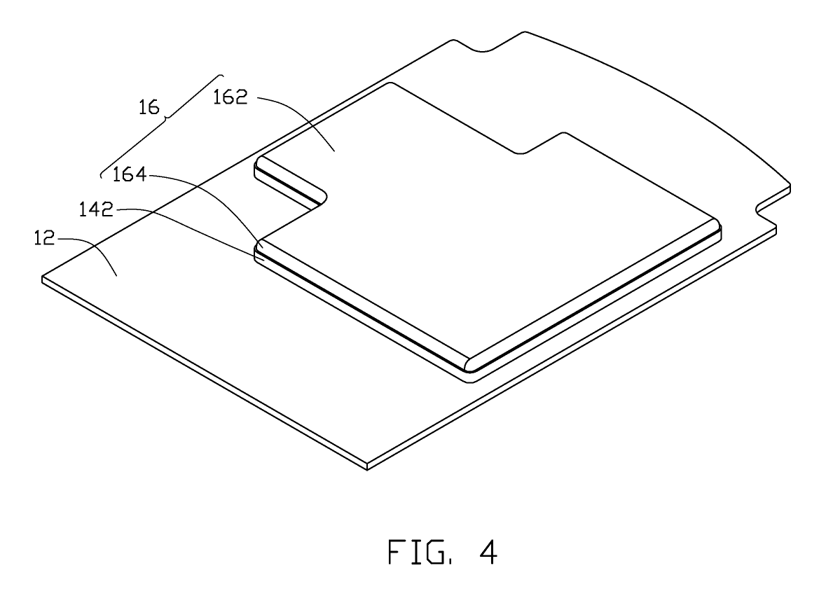

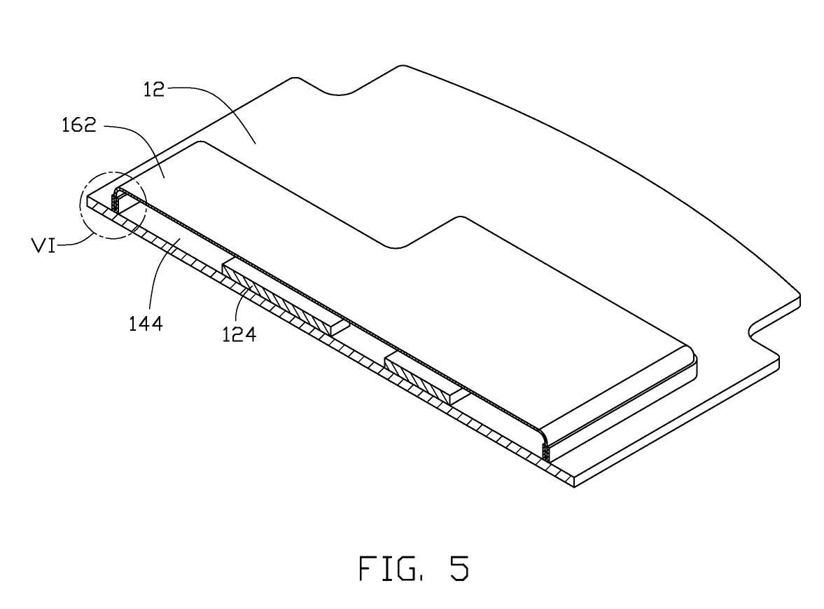

Referring to FIGS. 4-6, the cover 16 includes a top wall 162 and a peripheral side wall 164 extending from the peripheral edge of the top wall 162. Cover 16 is made from a material known to have shielding properties. The top wall 162 is sized and shape to correspond to the size and shape of the receiving space 144. The side wall 164 is configured to engage with the groove 149.

When assembling the shielding assembly 13, the base frame 14 is mounted to the circuit board 12 and accommodates the electronic components 124 in the receiving space 144. The cover 16 is mounted to the base frame 14 by the side wall 164 engaging with the groove 149 and the top wall 162 covering the receiving space 144.base frame Because the groove 149 surrounds the receiving space 144, the side wall 164 can be easily and firmly engaged with the groove 149, i.e., the cover 16 can be easily and firmly mounted to the base frame 14.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A shielding assembly for a portable electronic device, comprising:
a base frame including a peripheral wall, the peripheral wall enclosing a receiving space and defining a groove surrounding the receiving space; and
a cover covering the receiving space, the cover having a side wall corresponding to and for engaging with the groove of the base frame.

2. The shielding assembly as claimed in claim 1, wherein the peripheral wall has a surface facing the cover, the groove being defined in the surface facing the cover.

3. A portable electronic device, comprising:
a circuit board having at least one electronic component disposed thereon;
a base frame disposed on the circuit board, the base frame including a peripheral wall, the peripheral wall enclosing a receiving space for accommodating the at least one electronic component and defining a groove surrounding the receiving space; and
a cover covering the receiving space, the cover having a side wall corresponding to and for engaging with the groove of the base frame.

4. The shielding assembly as claimed in claim 2, wherein the peripheral wall has a surface facing the cover, the groove being defined in the surface.
